(19) United States
(12) Patent Application Publication
(10) Pub. No.: US 2008/0042302 A1
(43) Pub. Date: Feb. 21, 2008

(54) Plastic overmolded packages with molded lid attachments

(76) Inventors: Robert B. Crispell, Whitehall, PA (US); Robert Scott Kistler, Palmerton, PA (US); John W. Osenbach, Kutztown, PA (US)

Correspondence Address: Law Firm of Peter V.D. Wilde, 301 East Landing, Williamsburg, VA, 23185, US

(21) Appl. No.: 11/504,989

(22) Filed: Aug. 16, 2006

(51) Int. Cl. H01L 23/28

(52) U.S. Cl. 257/796

(57) ABSTRACT

The specification describes lidded IC plastic overmolded packages with chimney-type heat sinks. The packages have mechanical hold-down structures in the package lids that, when overmold is applied, form complementary hold-down structures in the overmold.

### RELATED APPLICATION

This application is related to application Serial No. (Crispell et al. Case 8-2-60) filed of even date herewith.

### FIELD OF THE INVENTION

This invention relates to plastic encapsulated packages for integrated circuit (IC) and related devices, and more specifically to plastic encapsulated packages requiring aggressive thermal management.

### BACKGROUND OF THE INVENTION

A widely used form of packaging for electronic devices such as IC devices is a plastic housing. Typically, IC chips are bonded to a substrate and a polymer is molded over the assembly to overmold the device. It is common for two or more IC chips to be assembled in a single overmolded package. Multiple chip packages are referred to as multi-chip-modules (MCMs).

As chip size decreases in state of the art IC technology, the problem of overheating in IC packages becomes more severe. It is further aggravated because polymers used for overmolding are poor thermal conductors. Thus while the plastic effectively encapsulates the devices, it traps the heat generated by the devices as well. In packages in which the IC chip is connected to the electrical terminations of the package with wire bonds, the thickness of the encapsulant must be sufficient to accommodate the height of the wire bonds. This results in a thick “cover” of plastic over the device. Since the thermal resistance of any given material decreases with increasing thickness, increased thickness further retards heat dissipation, all else being constant.

A wide variety of heat sink expedients have been proposed and used to address thermal management issues. Among these, and tailored for the types of packages with wire bonded IC chips, is the use of a conductive “chimney” that attaches to the top of an IC chip and becomes imbedded in the plastic overmold. The conductive chimney conducts heat away from the IC chip, through the thickness of the plastic overmold but through the chimney itself and not the plastic overmolded material to the top of the package. In some package designs, the top of the chimney is affixed to a lid. The lid may be made of metal, which effectively spreads the heat and conducts the heat to the external environment. In conventional designs, the chimney is attached to the lid using a thermal interface material (TIM). While any heat conductive material may be used for the chimney structure, silicon is preferred because of its thermo-mechanical compatibility with the silicon chips, low cost, availability, compatibility wih existing IC assembly equipment, and good thermal conductivity.

Device failures have been identified in these package designs. Improvement in the package design is needed to overcome these failures.

### BRIEF STATEMENT OF THE INVENTION

We have studied the failure modes of IC devices with chimney-type heat sinks, and have identified in detail the causes and effects of the failures. The two most common failure modes in these packages are resultant from the breakdown in the mechanical integrity of the chimney stack: i) the loss of attachment of the lid to the silicon chimney via the breakdown of the TIM/lid or TIM/chimney interface; and ii) the loss of attachment of the silicon chimney to the IC device via the breakdown of the chimney-IC adhesive/chimney or chimney-IC adhesive/IC device interface. When this attachment fails, the thermal conductive path from the IC chip to the external ambient is compromised. Among the reasons for detachment, a main cause is thermo-mechanical stress. When thermo-mechanical stresses become excessive, the lid detaches from the chimney or the chimney detaches from the IC device. We have developed an effective approach to reducing the adverse effects of thermo-mechanical stresses, and improving the thermo-mechanical stability of these IC packages. Important to the improved package designs is the recognition that the lid should be at least partially decoupled mechanically from the chimney while maintaining intimate thermal coupling. This is counter-intuitive to the tendency to approach the problem by making the bond between the chimney and the lid more mechanically robust, and consequently more rigid. The improvements basically rely on providing mechanical structure to the overmold and the lid so that the overmold itself aids in retaining the lid in place allowing for the partial mechanical decouling and intimate thermal coupling to be realized.

### BRIEF DESCRIPTION OF THE DRAWING

The invention may be better understood when considered in conjunction with the drawing in which:

FIGS. 1-4 are schematic views of a typical step sequence for fabricating an overmolded IC device package with a chimney-type heat sink;

FIGS. 5 and 6 are plan views of an MCM package of four IC chips and four chimneys that are used in this description to illustrate applicants' recognition of the failure mode in these devices;

FIGS. 7 and 8 are side views of an MCM package showing detachment modes wherein the lid separates from the chimneys, or causes failure in the bond between the chimneys and the IC chips;

FIGS. 9 and 10 illustrate improved package designs wherein mechanical features at the edge of the lid are used to aid in attaching the lid to the package;

FIGS. 11-13 are similar illustrations showing improved package designs wherein the mechanical features extend over the area of the lid.

### DETAILED DESCRIPTION OF THE INVENTION

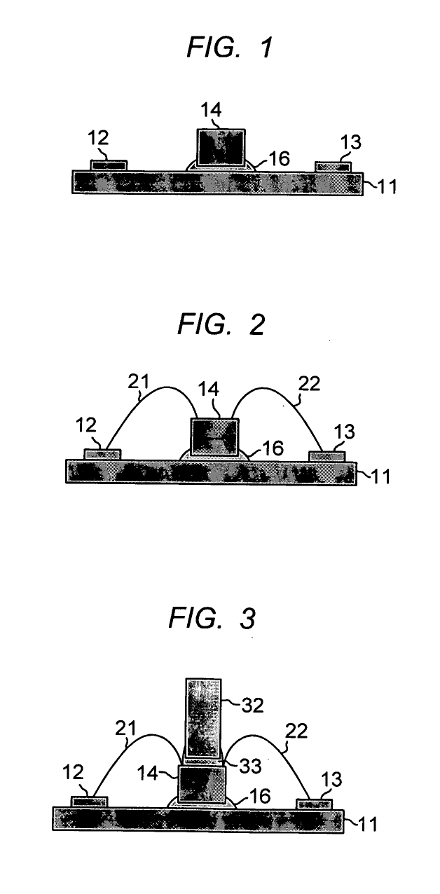

FIG. 1 shows an IC chip package comprising IC chip 14 bonded to substrate 11 with die attach material 16. The substrate may be any suitable substrate material, but is typically a printed circuit board (PCB). Wire bond pads 12 and 13 are formed on the substrate in known fashion. Referring to FIG. 2, wire bonds 21 and 22 are shown electrically connecting the bonded IC chip 14 to the PCB. A variety of IC chips generate significant heat during operation, and require special types of heat sinking to avoid overheating and failure. For example, microprocessors are typically large IC chips fabricated with state of the art design rules and have very dense device packing. They pose severe thermal management issues, and consequently are usually provided with special heat sink arrangements. One of those is shown in FIG. 3 with the heat sink in the form of silicon chimney 32. In this type of package, the IC chip is usually mounted on the PCB, and wire bonded for electrical interconnection. The wire bonds are attached to edge arrays of bond pads (not shown, for clarity) on the IC chip. This leaves a space in the center of the chip where the silicon chimney is mounted. The silicon chimney may be attached to the IC chip using a suitable attachment material 33. Attachment materials include but are not limited to, adhesives, such as epoxies or other adhesive polymer materials or solders. It is preferred that the adhesive material be a thermally conductive adhesive. Many standard and commercially available electrically conductive adhesives are also effective conductors of heat.

The example shown is a die bonded and wire bonded device. Other forms of IC devices, for example, flip-chip IC devices, may be used alternatively. The IC chips are typically encapsulated, but could comprise bare die. Reference to IC chip is meant to include either form. In the wire bonded example shown, the height of the silicon chimney is sufficient to accommodate the height of the wire bonds. The chimney height may be taller, or, in the case of devices without wire bonds, shorter. Silicon chimneys are usually designed for wire bonded IC chip packages.

With reference to FIG. 4, the assembly is then encapsulated in a polymer overmold 43. This protects the IC chip, the printed circuits on the surface of the PCB, and the wire bonds. A Thermal Interface Material (TIM) 45 is then applied to the overmold, and lid 41 attached to complete the device. The TIM serves both as a conductive medium, to conduct heat from silicon chimney 32 to lid 41, as well as an adhesive for retaining the lid in place. A suitable TIM for this application is Ablebond 2000T®, available from Ablestick Corp. The lid 41 serves as a heat spreader and conducts heat both laterally to cooler portion of the lid located away from the silicon chimney, as well as conduction and radiation to the ambient or other system designed heat dissipation stuctures. The lid is composed of thermally conductive material, such as copper. Typical thickness range for the lid is 0.1 mm to 1.0 mm.

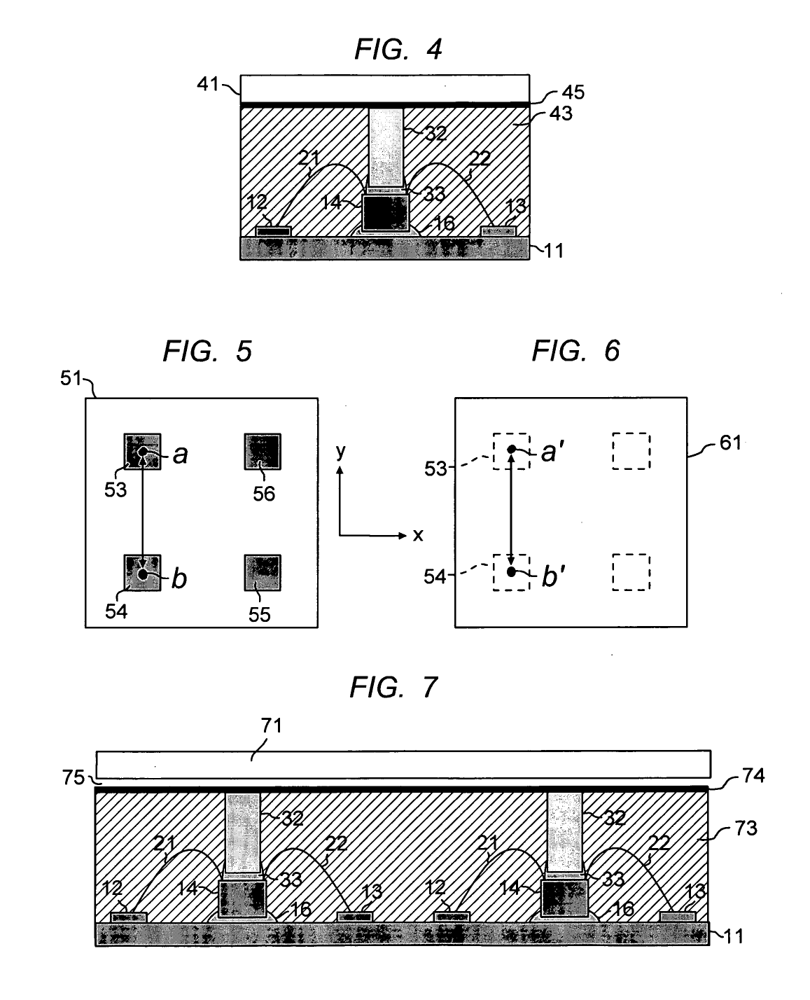

FIG. 5 is a schematic representation in plan view of an MCM 51 with four IC devices and four silicon chimneys, 53, 54, 55, 55 arranged as shown at four corners of a square. This figure is but one example of a variety of MCM device configurations and arrangements, having fewer or more devices and chimneys.

Chimneys 53 and 54 are spaced, center-to-center, at nominal distance a-b. When the MCM module is operated, and thermally cycled under different operating conditions, for example on and off, the distance a-b will change due to expansion/contraction of the various elements in the IC package. When a lid such as 61 is attached to the top of the chimneys, as shown in FIG. 6, the tops of the chimneys are coupled to both the lid and the substrate, such that differential stresses due to any movement that changes distance a-b is experienced by the chimney stack and chimney/lid interface. For example, if lid 61 is copper, a material commonly used for lids in packages of this kind, and the package subjected to significant temperature changes, the copper lid will undergo expansion/contraction dictated by the thermal coefficient of expansion, T_{c}, of copper. The distance a′-b′ is determined by that property, a property typically different from those that determine distance a-b. Thus the mismatch between a-b and a′-b′ can, depending on the thermo-mechnical properties of the materials used in the package construction, cause significant shear and bending stresses in the package. These tend to impact the interface between the chimney and the lid and the chimney and the IC device. In severe cases this will cause the lid to detach from the package, or the chimney to detach from the IC.

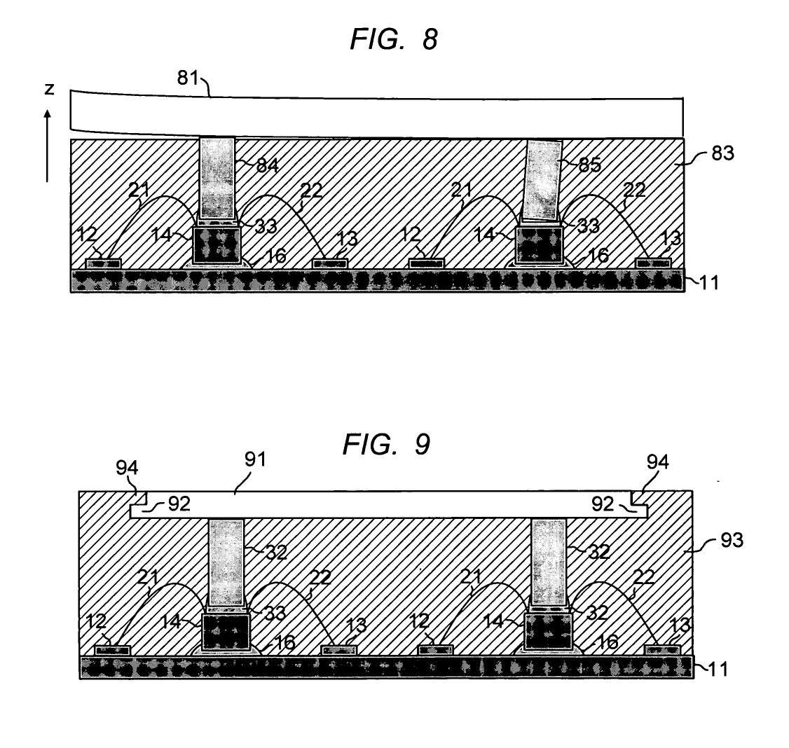

Detachment often occurs between the TIM and the lid. The TIM adheres well to the silicon chimney, but less firmly to the lid. FIG. 7 shows space 75 developing between the lid 71 and the TIM 74.

Strains produced by differential out of plane strains, and bending moments, lead to either or both lid failure and chimney to IC device failure. These are illustrated in FIG. 8: In lid failure, the silicon chimney 84 on the left side of the figure is raised with respect to the silicon chimney 85 on the right side of the figure. This disparity may be the result of differences in the expansion of the chimneys, or in other elements of the package. The out of plane strains may be sufficient to cause the lid 81 to completely or partially detach from encapsulant 83 (the TIM is omitted in this figure, for clarity). The out of plane strains like that illustrated in FIG. 8 may also cause a bending moment on the silicon chimney. Intuitively it can be appreciated that as the lid lifts on the left side in the figure (where it may be detached from the silicon chimney 84), it tilts. This imposes a bending moment on chimney 85, and may cause failure of the attachment at 33, i.e. the attachment between the chimney and the IC chip.

An approach to a more robust connection between the chimney heat sinks and the lid would appear to be to increase the integrity of the adhesive bond between these elements. However, we have found that a more effective approach is just the opposite. The rigid attachment between these elements is found to be at least partly responsible for the problem of lid failure. Accordingly, new package structures have been designed wherein the overmold is provided with mechanical features that aid in the attachment of the lid. The lid is provided with complementary mechanical features. In the package design shown in FIGS. 1-4, it will be appreciated that if there is a failure in the adhesive attachment, there are no mechanical elements available to hold down the lid on the package. Mechanical lid hold-downs are a feature of the designs described below.

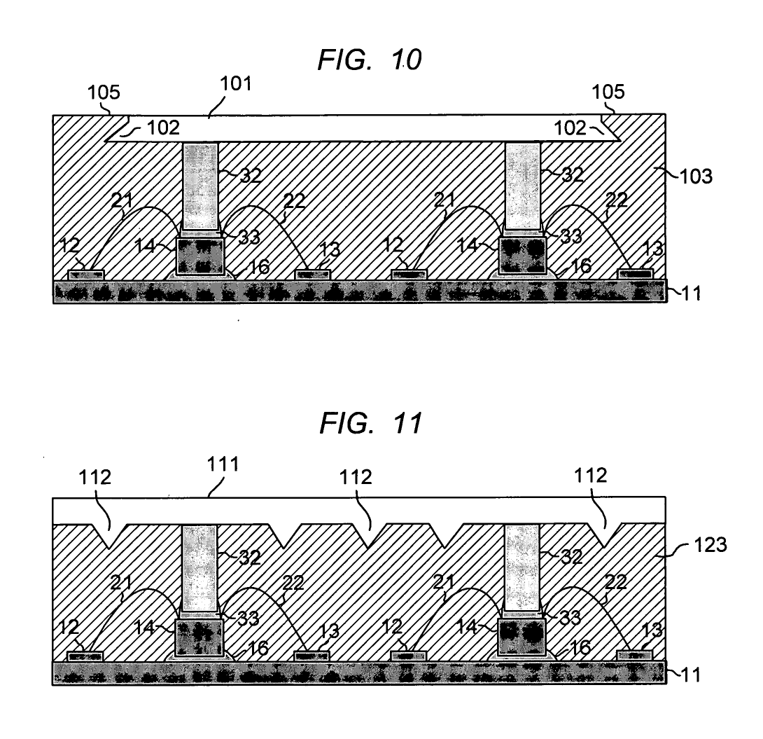

FIG. 9 shows a rabbet 94 formed along the edge of the lid. Overmold 93 has a mechanical hold-down feature 94 that bears on the rabbet 92 to hold down the lid 91. To form this structure it is useful to attach the lid to the chimneys prior to applying the overmold 93. However, the attachment need only be a temporary attachment until the overmold 93 is formed. The preferred attachment materials applied between the chimneys and the lid are relatively soft conductive polymers. It is also preferred that the conductive polymer between the heat sink and the lid not be an adhesive polymer, or a relatively weak adhesive polymer. Accordingly, silicon resins are preferred over typical epoxies. A suitable material for this application is Gelease MG 121, available from Lord Thermoset.

If desired, conventional TIM may be used, in addition to the lid hold-downs described here, to bond the lid. In this case it will be recognized that the TIM is applied only to the chimneys, not to the overmold as shown in FIG. 4. In fact, the step sequence just describes precludes applying TIM directly to the overmold. If TIM in the interface between the lid and the overmold is preferred, it can be applied to the lid surface prior to attaching the lid to the chimneys.

It should be noted that for designs engineered to accommodate the thermal mechanical properties of the lid, mold compound, silicon chimney, IC device, chimney die attach, IC die attach, and substrate material, a TIM may not be required to insure a highly thermally coupled interface between the chimney and the lid, via physical contact of the lid and the chimney. However, process control during assembly may make such designs less robust than those that include a TIM material in the design.

Since the lid hold-down features 94 are formed during the molding step, they become part of and integral with the remainder of the overmold. The lid hold-downs may be designed in many forms, only a few of which are shown here. An optional form of lid hold-down is illustrated in FIG. 10, wherein the lid hold-down features 105 are formed as a result of molding the overmold 103 around re-entrant sidewalls 102 in the lid 101. Note that the hold-down features in the overmold are complementary in shape to the hold-down features 102 in the lid.

In the embodiments shown in FIGS. 9 and 10 the lid hold-downs are formed along the edges of the lid. However, strains due to the mechanical stresses described above may occur in the center portions of the lid as well. These may cause detachment problems in the middle of the lid. To add greater hold-down power, lid hold-downs may be formed at locations across the entire lid area. These may be described as area arrayed lid hold-downs.

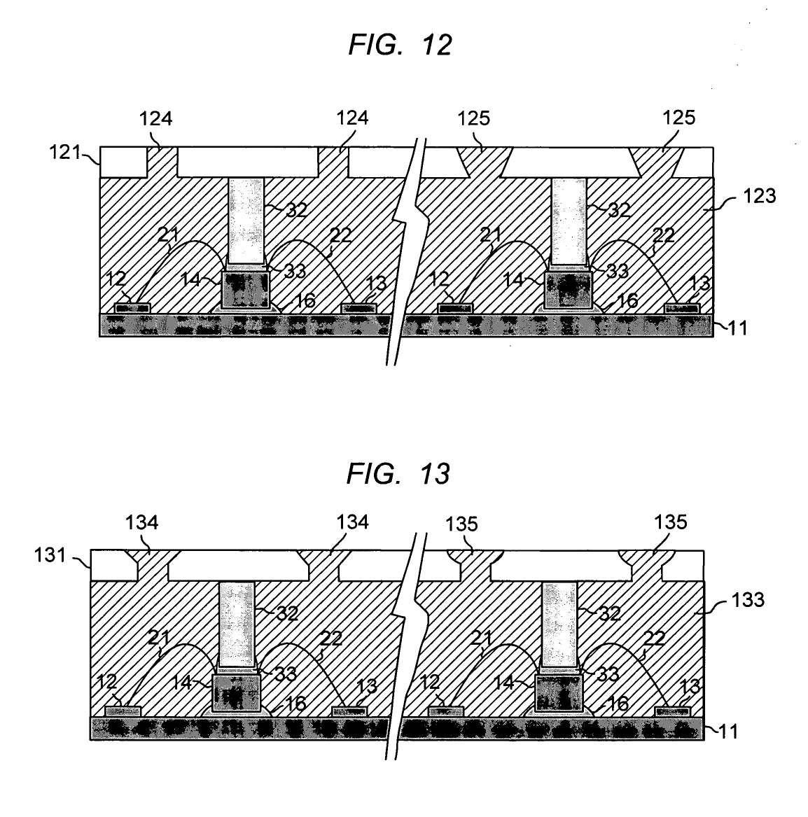

One example of area arrayed hold-downs shown in FIG. 11. Grooves 112 are formed in lid 11. When the encapsulant 123 is applied, it fills the grooves 112, increasing the surface area of the contact between the lid and the overmold. It should be appreciated that this figure, as well as other figures herein, is not drawn to scale. The features have the size shown for clarity. Actual features used may be larger or smaller.

The grooves shown in FIG. 12 are V-shaped. A wide variety of shapes may be chosen. For example, the grooves may be dado shaped, V-grooves with re-entrant sidewalls, T-shaped, W shaped, etc.

Four additional examples of area-arrayed lid hold-downs are shown in FIGS. 12 and 13. Both figures show devices with chimney type heat sinks in two separate embodiments. They are grouped for convenience, but represent four different device structures wherein four different lid hold-down features are shown at 124, 125, 134 and 135. The hold-downs shown at 124 are holes formed through lid 121. These function in a manner similar to dado joints. The hold-downs shown at 125 in FIG. 12 function in a manner similar to dovetail joints. The hold-downs shown at 134 and 135 in FIG. 13 resemble rivets. It should be apparent that all of these structures have hold-downs that effectively provide forces that retain the package lid on the overmold. It should be evident that the hold-down configurations shown as area-arrayed hold-downs can be used as edge hold-downs, i.e., along the edges of the lid as described above in connection with FIGS. 9 and 10.

As indicated above, a wide variety of structures may be designed following the principles of the invention. One of these principles is the provision of lid hold-downs in the overmold body. The term hold-down is described above in clear detail, and several embodiments are shown to aid in defining its meaning. It refers to any shape formed in the mold body, and integral with the mold body, that in combination with one or more structural shapes in the lid of the package, exerts a force retaining the lid on the package. Thus while it may not be a previously established term of art, the use of this term in describing the invention is clear and apt.

As just mentioned, lid hold-downs involve hold-down structures in both the lid and the overmold. The shape of these hold-down structures in the lid and overmold respectively are essentially complementary. That is, the shape of the hold-down feature in the lid is complementary to the shape of the hold-down feature in the overmold body.

As mentioned above, the invention is applicable primarily to MCM packages, which is intended to mean that each package contains N IC devices, where N is at least two, with each IC device being provided with a heat sink.

Various additional modifications of this invention will occur to those skilled in the art. All deviations from the specific teachings of this specification that basically rely on the principles and their equivalents through which the art has been advanced are properly considered within the scope of the invention as described and claimed.

1. An overmolded MCM IC package comprising:
a. a substrate,
b. at least two semiconductor IC devices attached to the substrate,
c. at least two heat sinks, with a heat sink attached to each IC device, the heat sinks having a top and a bottom, with the bottom attached to an IC device,
d. a polymer overmold encapsulating the semiconductor devices and the heat sinks, the overmold forming a top surface with the top of the heat sinks exposed, the polymer overmold having a plurality of lid hold-downs on the top surface,
e. a lid attached to the overmold, the lid having a plurality of lid hold-downs, with the lid hold-downs in the overmold engaging the lid hold-downs in the lid.

2. The package of claim 1 wherein the lid hold-downs in the overmold and the lid each have a shape, and the shape of the hold-downs in the overmold conforms to the complement of the shape of the lid hold-downs in the lid.

3. The package of claim 2 wherein the IC devices are electrically connected to the substrate with wire bonds.

4. The package of claim 2 wherein a first conductive polymer is selectively placed between the heat sinks and the lid.

5. The package of claim 4 wherein a second conductive polymer is selectively placed between the overmold and the lid, and the first conductive polymer is different from the second conductive polymer.

6. The package of claim 4 wherein the first conductive polymer is not an adhesive polymer.

7. The package of claim 2 wherein the heat sink is silicon.

8. The package of claim 2 wherein the lid is copper.

9. The package of claim 2 having at least four IC devices.

10. Method for the manufacture of an overmolded MCM IC package comprising:
a. attaching N semiconductor IC devices to a substrate, where N is at least 2,
b. attaching N heat sinks to the IC devices, with each IC device provided with a heat sink, the heat sinks having a bottom attached to an IC device and a top,
c. attaching a lid to the top of the heat sinks, the lid having a plurality of lid hold-downs,
d. molding an overmold encapsulating the IC devices and the heat sinks, wherein the step of molding the overmold includes forming a plurality of lid hold-downs integral with the overmold, with the lid hold-downs in the overmold filling the lid hold-downs in the lid.

11. The method of claim 10 wherein the lid hold-downs in the overmold and the lid each have a shape, and the shape of the hold-downs in the overmold conforms to the complement of the shape of the lid hold-downs in the lid.

12. The method of claim 11 wherein the IC devices are electrically connected to the substrate with wire bonds.

13. The method of claim 11 wherein the lid is attached to the heat sinks using a first conductive polymer.

14. The method of claim 13 wherein a second conductive polymer is applied to the lid prior to attaching the lid to the heat sinks and the first conductive polymer is different from the second conductive polymer.

15. The method of claim 13 wherein the first conductive polymer is not an adhesive polymer.

16. The method of claim 11 wherein the heat sink is silicon.

17. The method of claim 11 wherein the lid is copper.

18. The method of claim 11 wherein N is at least 4.
